(19) United States
(12) Patent Application Publication
(10) Pub. No.: US 2014/0261691 A1
(43) Pub. Date: Sep. 18, 2014

(54) THIN FILM SOLAR CELL AND FABRICATION METHOD THEREFOR

(71) Applicant: TSMC SOLAR LTD., Taichung City (TW)

(72) Inventors: Chien-Yao Huang, New Taipei City (TW); Yung-Sheng Chiu, Fuxing Township (TW); Wen-Chin Lee, Baoshan Township (TW)

(73) Assignee: TSMC SOLAR LTD., Taichung City (TW)

(21) Appl. No.: 14/164,288

(22) Filed: Jan. 27, 2014

Related U.S. Application Data
(60) Provisional application No. 61/777,470, filed on Mar. 12, 2013.

(51) Int. Cl. H01L 31/032; H01L 31/18

(52) U.S. Cl. CPC H01L 31/0322; H01L 31/1828
USPC 136/262; 438/84

(57) ABSTRACT

A method is disclosed for manufacturing an absorber layer, such as a CIS-based absorber layer, in a thin film solar cell, such as a CIS-based thin film solar cell. One method includes a selenization step, an annealing step, and a sulfuration step. Another method includes an annealing step and a sulfuration step. Additionally, a disclosed CIS-based absorber layer has a surface-to-bottom ratio of gallium which is greater than that for a conventional absorber layer and the ratio of sulfur to sulfur-plus-selenium is less than that for a conventional absorber layer. Also provided is a process for producing an absorber layer, such as a CIS-based absorber layer, over a large area where the layer is capable of achieving both a high open circuit voltage and a high fill factor by preferable depth composition profile through controllable gallium-diffusion/sulfur-incorporation and the enlarged grain size.

### RELATED AND CO-PENDING APPLICATION

This application claims priority to co-pending U.S. provisional patent application entitled “Thin Film Solar Cell and Fabrication Method Therefor”, Ser. No. 61/777,470 filed on 12 Mar. 2013; the entirety of which is hereby incorporated herein by reference.

### BACKGROUND

Thin film solar cells, also known as thin film photovoltaic cells, are used to convert light energy directly into electrical energy. The manufacture of thin film solar cells includes the steps of depositing one or more thin film layers of photovoltaic material on a substrate, such as a glass substrate. Typically, thin film solar cells include a substrate, a back electrode layer, an absorber layer, a buffer layer, and a window layer. The absorber layer may be a “CIS-based” absorber, where “CIS” generally refers to copper-indium-selenium. In typical conventional thin film solar cells, the CIS-based absorber layer is a p-type layer, the buffer layer is an n-type layer, and the window layer is an n-type transparent conductive oxide window.

Known methods of manufacturing thin film solar cells include one of two methods for fabricating the absorber layer: the “multi-source co-evaporation” method and the “sulfuration after selenization” (sometimes referred to herein as “SAS”) method. Each method has its advantages and disadvantages. For example, while the multi-source co-evaporation method has achieved high conversion efficiency for relatively small-sized CIS-based absorber layers for thin film solar cells, there is a serious problem with the uniformity of the film's composition. Additionally, the multi-source co-evaporation method currently does not have the capability to be used on an industrial production process scale. Additionally, the equipment needed for this method is complicated and expensive. On the other hand, the SAS method achieves uniform absorber formation for a relatively large size (i.e., more than 1 square meter), efficiently uses the materials needed to form the absorber layer, and uses simpler and less costly equipment than the multi-source co-evaporation method. However, the SAS method suffers from low conversing efficiency and a low fill factor.

Therefore, there is a need for a manufacturing method of CIS-based absorber layers for thin film solar cells that have, among other attributes, a high uniformity of film composition over a large area, an efficient use of materials, and results in an absorber layer with a high fill factor.

### BRIEF DESCRIPTION OF THE DRAWINGS

FIG. 1 is a simplified block diagram of a conventional CIS-based thin film solar cell.

FIG. 2 is a time versus temperature graph for a conventional SAS process for a CIS-based absorber layer.

FIG. 3 is a time versus temperature graph for forming a CIS-based absorber layer according to an embodiment of the present subject matter.

FIG. 4 is a flow diagram of a method for manufacturing an absorber layer according to an embodiment of the present subject matter.

FIG. 5 is a time versus temperature graph for forming a CIS-based absorber layer according to another embodiment of the present subject matter.

FIG. 6 is a flow diagram of a method for manufacturing an absorber layer according to another embodiment of the present subject matter.

FIG. 7 is a graph comparing open circuit voltage versus fill factor for a CIS-based thin film solar cell having a CIS-based absorber layer fabricated using a conventional SAS process and for a CIS-based thin film solar cell having a CIS-based absorber layer fabricated according to embodiments of the present subject matter.

FIG. 8A is a graph comparing a profile of gallium in a CIS-based absorber layer fabricated using a conventional SAS process and in a CIS-based absorber layer fabricated according to embodiments of the present subject matter.

FIG. 8B is a graph comparing a profile of sulfur in a CIS-based absorber layer fabricated using a conventional SAS process and in a CIS-based absorber layer fabricated according to embodiments of the present subject matter.

FIG. 9A is a picture showing a cross-section of certain layers of a thin film solar cell fabricated according to embodiments of the present subject matter.

FIG. 9B is a picture showing a cross-section of certain layers of a conventional thin film solar cell fabricated using conventional SAS methods.

FIG. 10 is a picture showing a cross-section of a CIS-based absorber layer fabricated according to embodiments of the present subject matter.

### DETAILED DESCRIPTION

With reference to the figures, various embodiments of a thin film solar cell and fabrication methods therefor are described. In order to more fully understand the present subject matter, a brief description of the thin film solar cell and fabrication methods therefor will be helpful.

With attention drawn to FIG. 1, a simplified block diagram of a conventional CIS-based thin film solar cell 100 is presented. Typical thin film solar cell manufacturing methods entail sequentially depositing separate layers on a substrate by using one or more known deposition methods. The bottom layer is typically the substrate layer 101, which may be a glass substrate. The next layer is a back electrode layer 102 which typically is metallic. The next layer is a CIS-based thin film absorber layer 103, which may typically be a p-type layer. The CIS-based thin film absorber layer will be discussed in more detail below. The next layer is a buffer layer 104 which typically may be an n-type layer. The top layer is a window layer 105 which may typically be an n-type transparent conductive oxide layer.

The CIS-based absorber layer 103 may be fabricated using a conventional SAS method which involves depositing a metal precursor film on the metal back electrode layer 102. The metal precursor film is typically composed of copper (“Cu”), indium (“In”), and gallium (“Ga”). A device, which includes the substrate 101, the back electrode layer 102 and the metal precursor film, is placed in a machine for performing the sulfuration after selenization process to thereby form the CIS-based absorber layer 103. The machine, which includes a heating system and a replaceable atmosphere, is used for holding and treating the device in an atmosphere containing a specific gas (e.g., a gas containing a selenium source or a gas containing a sulfur source) for a certain duration of time at a certain temperature. The conventional SAS process requires a selenization step followed by a sulfuration step, each performed at a particular holding temperature for a particular amount of time.

Considering FIG. 2, shown is a time versus temperature graph 200 for a conventional SAS process for a CIS-based absorber layer. During the conventional SAS process, the atmosphere inside the machine is replaced with an inert gas, such as nitrogen gas, and then a selenium source is introduced to the atmosphere, as is known in the art. The temperature inside the machine is increased to a holding temperature, shown as T₁ (designated 201) in FIG. 2, for a predetermined amount of time, shown as Δt₁ (designated 211). The selenization step is shown as plateau 210 in FIG. 2. After the selenization step is completed, the selenium atmosphere in the machine is replaced with a sulfur atmosphere, as is known in the art. The temperature inside the machine is increased to a holding temperature, shown as T₂ (designated 202) in FIG. 2, for a predetermined amount of time, shown as Δtₜ (designated 221). The sulfuration step is shown as plateau 220 in FIG. 2. After the completion of the sulfuration step, the temperature is reduced to ambient and then the atmosphere in the machine is replaced with ambient atmosphere. The CIS-based absorber layer 103 is thus formed.

Although the conventional SAS method described above has good potential for uniformly forming a CIS-based absorber layer on a large area at an industrial manufacturing scale, high conversion efficiency cannot easily be achieved due to the inseparability between gallium diffusion and sulfur incorporation inherent in the conventional SAS method. In the conventional SAS method, thermal diffusion of constituent elements determines the composition profile and compound formation in the absorber layer. Since the diffusion rate of gallium is slower than the diffusion rate of other elements, gallium inveterately accumulates at the bottom of the absorber layer and thus has no effective contribution to improve the “effective band gap” and conversion efficiency of the absorber layer. As is known in the art, the “effective band gap” is the minimum optical band gap of material and is determined from quantum efficiency (“QE”) curves by the energy value calculated from the wavelength value where a 20% QE is observed for the long wavelengths.

Importantly, gallium diffusion toward the surface of the absorber layer would improve the utility of the gallium in the absorber layer as well as enlarge the “effective band gap” of the absorber. Consequently, the open current voltage, the fill factor, and the conversion efficiency of the absorber layer would all increase, which is desirable. As is known in the art, fill factor (“FF”) is the ratio of actual maximum obtainable power (“P_{MAX}”) to the product of the open circuit voltage (“V_{OC}”) and short circuit current (“I_{SC}”):

$$F F = \frac{{P}_{MAX}}{{V}_{OC} \times {I}_{SC}}$$

A high FF is indicative of low current dissipation in the cell due to internal losses.

One method used in conventional SAS to improve gallium diffusion toward the surface of the absorber layer is to modify the sulfuration step 220 by increasing T₂ and Δt₂ shown in FIG. 2. However, while an extended sulfuration step at a higher holding temperature enhances gallium diffusion toward the surface of the absorber layer and thereby increases V_{OC}, doing so results in the unintended consequence of excess sulfur incorporation which deteriorates the p-n junction between the absorber layer 103 and the buffer layer 104 due to surface etching of the absorber layer by the sulfur and by the formation of molybdenum-selenium-sulfur (“Mo—Se—S”) compounds which weakens the ohmic back-contact. Thus, the excess sulfur incorporation operates to reduce the fill factor of the cell. This inseparability between increased gallium diffusion and excess sulfur incorporation limits the ability of the conventional SAS process from achieving both a high V_{OC} and a high FF.

Now considering FIG. 3, a time versus temperature graph 300 for forming a CIS-based absorber layer according to embodiments of the present subject matter is presented. A substrate is layered with a back electrode layer upon which a metal precursor film is deposited. The metal precursor, which may sometimes be referred to as a CIS-based semiconductor precursor, may contain any one or more of the following materials Cu, Ga, In, Cu—Ga, Cu—In, In—Ga, Cu—In—Ga alloy. In some embodiments, the metal precursor film also includes selenium and/or sulfur.

In some embodiments, the CIS-based semiconductor precursor is a pentanary Cu-III-VI₂ group chalcopyrite semiconductor having as components copper, a III group material (e.g., indium and/or gallium), and VI group material (e.g., selenium and/or sulfur). In some embodiments, the CIS-based semiconductor precursor contains a selenide such as CuInSe₂, CuGaSe₂, and/or Cu(InGa)Se₂. In some embodiments, the CIS-based semiconductor precursor contains a sulfide such as CuInS₂, CuGaS₂, and/or Cu(InGa)S₂. In some embodiments, the CIS-based semiconductor precursor contains a compound containing both selenium and sulfur, such as CuIn(Se,S)₂, CuGa(Se,S)₂, and/or Cu(InGa)(Se,S)₂.

A device, which includes a substrate, a back electrode layer, and a metal precursor film, is placed in a machine for performing a selenization step, an annealing step, and a sulfuration step, according to embodiments of the present subject matter, to thereby form a CIS-based absorber layer. The machine, which includes a heating system and a replaceable atmosphere, is used for holding and treating the device in an atmosphere containing a specific gas (e.g., a gas containing a selenium source, an inert gas such as nitrogen or argon, or a gas containing a sulfur source) for a certain duration of time at a certain temperature as described below.

According to embodiments of the present subject matter, the atmosphere inside the machine is replaced with an inert gas, such as nitrogen gas, and then a selenium source is introduced to the atmosphere. In some embodiments, the selenium source is hydrogen selenide. The temperature inside the machine is increased to a holding temperature, shown as T₃ (designated 303) in FIG. 3, for a predetermined amount of time, shown as Δt₃ (designated 331). In some embodiments, T₃ is in the range of 200° C. to 800° C., inclusive. In some embodiments, Otₐ is in the range of ≧0 minute to 300 minutes, inclusive. The selenization step is shown as plateau 330 in FIG. 3.

After the selenization step is completed, the selenium atmosphere in the machine is replaced with an inert gas atmosphere, such as nitrogen or argon. The temperature inside the machine is increased to a holding temperature, shown as T₄ (designated 304) in FIG. 3, for a predetermined amount of time, shown as Δt₄ (designated 341). In some embodiments, T₄ is in the range of 200° C. to 800° C., inclusive. In some embodiments, Δt₄ is in the range of ≧0 minute to 300 minutes, inclusive. In some embodiments, T₃≦T₄. The annealing step is shown as plateau 340 in FIG. 3.

After the annealing step is completed, the temperature inside the machine is decreased to a holding temperature, shown as T₅ (designated 305) in FIG. 3, and then the inert gas atmosphere in the machine is replaced with a sulfur atmosphere, i.e., an atmosphere having a sulfur source. In some embodiments, the sulfur source is hydrogen sulfide. Thereafter the device is held for a predetermined amount of time, shown as Δt₅ (designated 351) at the holding temperature T₅. In some embodiments, T₅ is in the range of 200° C. to 600° C., inclusive. In some embodiments, Δt₅ is in the range of ≧0 minute to 300 minutes, inclusive. In some embodiments, T₅≦T₄. In some embodiments, T₃≦T₅≦T₄. The sulfuration step is shown as plateau 350 in FIG. 3. After the completion of the sulfuration step, the temperature is reduced to ambient and then the atmosphere in the machine is replaced with ambient atmosphere. A CIS-based absorber layer is thus formed.

In some embodiments, the holding temperature (T₁) and the duration (Δt₁) of the selenization step in the conventional SAS method in FIG. 2 is the same, respectively, as the holding temperature (T₃) and the duration (Δt₃) of the selenization step in the present subject matter in FIG. 3.

FIG. 4 shows a flow diagram 400 of a method for manufacturing an absorber layer according to embodiments of the present subject matter. At step 401a device is provided upon which a CIS-based absorber layer is to be formed. The device may include a substrate, a back electrode layer, and a metal precursor film. The metal precursor film may be as described above with respect to FIG. 3. At step 402, a first process is performed on the device at a temperature T₃ for a duration of Δt₃. The first process may be the selenization step described above with respect to FIG. 3. At step 403, a second process is performed on the device at a temperature T₄ for a duration of Δt₄. The second process may be the annealing step described above with respect to FIG. 3. At step 404, a third process is performed on the device at a temperature T₅ for a duration of Δt₅. The third process may be the sulfuration step described above with respect to FIG. 3.

Now considering FIG. 5, a time versus temperature graph 500 for forming a CIS-based absorber layer according to embodiments of the present subject matter is presented. A treatment object including a CIS-based semiconductor precursor, as described above, or a metal precursor containing selenium and/or sulfur, as described above, is placed in a machine, such as the machine described above, for performing an annealing step and a sulfuration step, according to embodiments of the present subject matter, to thereby form a CIS-based absorber layer.

The atmosphere in the machine is replaced with an inert gas atmosphere, such as nitrogen or argon. The temperature inside the machine is increased to a holding temperature, shown as T₆ (designated 506) in FIG. 5, for a predetermined amount of time, shown as Δt₆ (designated 561). In some embodiments, T₆ is in the range of 200° C. to 800° C., inclusive. In some embodiments, Δt₆ is in the range of ≧0 minute to 300 minutes, inclusive. The annealing step is shown as plateau 560 in FIG. 5.

After the annealing step is completed, the temperature inside the machine is decreased to a holding temperature, shown as T₇ (designated 507) in FIG. 5, and then the inert gas atmosphere in the machine is replaced with a sulfur atmosphere, i.e., an atmosphere having a sulfur source. In some embodiments, the sulfur source is hydrogen sulfide. Thereafter the device is held for a predetermined amount of time, shown as Δt₇ (designated 571) at the holding temperature T₇. In some embodiments, T₇ is in the range of 200° C. to 600° C., inclusive. In some embodiments, Δt₇ is in the range of ≧0 minute to 300 minutes, inclusive. In some embodiments, T₇≦T₆. The sulfuration step is shown as plateau 570 in FIG. 5. After the completion of the sulfuration step, the temperature is reduced to ambient and then the atmosphere in the machine is replaced with ambient atmosphere. A CIS-based absorber layer is thus formed.

FIG. 6 shows a flow diagram 600 of a method for manufacturing an absorber layer according to embodiments of the present subject matter. At step 601a treatment object is provided upon which a CIS-based absorber layer is to be formed. The treatment object includes a CIS-based semiconductor precursor, as described above, or a metal precursor containing selenium and/or sulfur, as described above. At step 602, a first process is performed on the device at a temperature T₆ for a duration of Δt₆. The first process may be the annealing step described above with respect to FIG. 5. At step 603, a second process is performed on the device at a temperature T₇ for a duration of Δt₇. The second process may be the sulfuration step described above with respect to FIG. 5.

Embodiments of the present subject matter provide a method of manufacturing a CIS-based absorber layer on a large area device for a CIS-based thin film solar cell at an industrial manufacturing scale. Also provided by embodiments of the present subject matter is a device, such as a CIS-based thin film solar cell, which incorporates the CIS-based absorber layer described above. Additionally, embodiments of the present subject matter provide a CIS-based absorber layer which achieves both a high V_{OC} and a high FF by controllable gallium diffusion and sulfur incorporation in the absorber layer. Furthermore, embodiments of the present subject matter allow for an enlarged grain size in the absorber layer thereby further enhancing the utility of source materials in a CIS-based thin film absorber.

Embodiments of the present subject matter provide a process which separates the gallium diffusion from the sulfur incorporation. The extent of gallium diffusion is controlled by the parameters of the annealing step. The extent of sulfur incorporation is controlled by both the selenization step and the sulfuration step. Accordingly, the depth composition profile of the absorber layer can be optimized due to the separation of the control of gallium diffusion from the control of sulfur incorporation. Additionally, the utility of the gallium in the absorber layer is increased, the diffusion of gallium through the absorber layer is increased, and therefore the “effective band gap” is increased without paying the penalty of excess sulfur incorporation. Furthermore, the enlarged grain size due to the processes provided by embodiments of the present subject matter (when compared to the grain size resulting from using conventional SAS methods) reduces recombination loss through grain boundaries and produces a thicker absorber layer for more effective light absorption.

FIG. 7 is a graph 700 comparing open circuit voltage (“V_{oc}”) versus fill factor (“FF”) for a CIS-based thin film solar cell having a CIS-based absorber layer fabricated using a conventional SAS process (triangular data points 701) and for a CIS-based thin film solar cell having a CIS-based absorber layer fabricated according to embodiments of the present subject matter (square data points 702). As can be seen from analyzing the graph 700, for the conventional SAS process, the data points tend downward as V_{OC} increases as shown by the dotted line 703. This tendency is indicative of the trade-off inherent in conventional SAS methods between V_{OC} and FF, as discussed above. Conversely, the data points for embodiments of the present subject matter tend upward as V_{OC} increases as shown by the dotted line 704. This tendency reveals that a CIS-based thin film solar cell fabricated according to embodiments of the present subject matter is capable of achieving both a high V_{OC} and a high FF.

With attention now drawn to FIG. 8A, a graph is shown comparing the profile of gallium in a CIS-based absorber layer fabricated using a conventional SAS process (represented by the line 803A traversing the graph from point 801A on the left to point 802A on the right) with the profile of gallium in a CIS-based absorber layer fabricated according to embodiments of the present subject matter (represented by the line 812A traversing the graph from point 810A on the left to point 811A on the right). The data for the gallium profile in FIG. 8A was obtained by energy-dispersive x-ray spectroscopy (“EDX”). Along the x-axis, the leftmost value shown (“0”) is the bottom of the CIS-base absorber layer and the rightmost value shown (“100”) is the top of the CIS-based absorber layer. The values on the x-axis in between represent a percentage of the distance through the thickness of the CIS-based absorber layer taken from the bottom of the CIS-based absorber layer (distance from bottom divided by the thickness of the CIS-based absorber layer). The values along the y-axis represent the ratio of the concentration of gallium (“[Ga]”) to the sum of the concentrations of copper, indium, and gallium (“[Cu]+[In]+[Ga]”) in the CIS-based absorber layer.

As can be seen from analyzing the graph in FIG. 8A, the concentration of gallium for the conventional SAS process (line 803A) tends markedly downward from the bottom of the absorber layer (801A) to the top of the absorber layer (802A) which is symptomatic of one of the drawbacks of the conventional SAS process: low gallium diffusion and the resultant accumulation of gallium at the bottom of the CIS-based absorber layer. In contrast, the concentration of gallium for fabrication methods according to embodiments of the present subject matter (line 812A) is much “flatter” from the bottom of the absorber layer (810A) to the top of the absorber layer (811A) than for line 803A. The relative flatness of the gallium profile shown by line 812A indicates a higher gallium diffusion throughout the CIS-based absorber layer for embodiments of the present subject matter than for conventional SAS methods. In FIG. 8A, the surface-to-bottom ratio of [Ga] for the conventional SAS method is approximately 3.7% while the surface-to-bottom ratio of [Ga] for embodiments of the present subject matter is approximately 50%. Typically, for the conventional SAS method, the ratio of [Ga] are in the 0-29% range. For embodiments of the present subject matter, the ratio of [Ga] is >40% and ratios between 40% to 55% have been repeatedly achieved.

As stated above, the extent of gallium diffusion toward the surface of the CIS-based absorber layer is controllable using fabrication methods incorporating embodiments of the present subject matter by controlling the annealing step discussed above.

FIG. 8B illustrates a graph comparing a profile of sulfur in a CIS-based absorber layer fabricated using a conventional SAS process (represented by the line 803B traversing the graph from point 801B on the left to point 802B on the right) with the profile of sulfur in a CIS-based absorber layer fabricated according to embodiments of the present subject matter (represented by the line 812B traversing the graph from point 810B on the left to point 811B on the right). The data for the sulfur profile in FIG. 8B was obtained by EDX. Along the x-axis, the leftmost value shown (“0”) is the bottom of the CIS-base absorber layer and the rightmost value shown (“100”) is the top of the CIS-based absorber layer. The values on the x-axis in between represent a percentage of the distance through the thickness of the CIS-based absorber layer taken from the bottom of the CIS-based absorber layer (distance from bottom divided by the thickness of the CIS-based absorber layer). The values along the y-axis represent the ratio of the concentration of sulfur (“[S]”) to the sum of the concentrations of copper, indium, and gallium (“[Cu]+[In]+[Ga]”) in the CIS-based absorber layer.

As can be seen from analyzing the graph in FIG. 8B, the concentration of sulfur for the conventional SAS process (line 803B) is higher than the concentration of sulfur for embodiments of the present subject matter (line 812B) which is symptomatic of another one of the drawbacks of the conventional SAS process: excess sulfur incorporation in the absorber layer which, as discussed above, operates to reduce the fill factor of the CIS-based thin film solar cell. In contrast, the concentration of sulfur in the absorber layer for fabrication methods according to embodiments of the present subject matter (line 812B) is lower throughout the thickness of the absorber layer.

As stated above, the extent of sulfur incorporation in the CIS-based absorber layer is controllable using fabrication methods incorporating embodiments of the present subject matter by controlling the selenization step and the sulfuration step as discussed above.

Another way to show that there is less sulfur incorporation into the CIS-based absorber layer for methods according to embodiments of the present subject matter as compared to conventional SAS methods is through inductively coupled plasma mass spectrometry (“ICP”). Using ICP, the ratio of the concentration of sulfur (“[S]”) to the concentration of sulfur-plus-selenium (“[S]+[Se]”) in a CIS-based absorber layer fabricated using embodiments of the present subject matter was shown to be less than 0.2 and was repeatedly shown to be between 0.15 to 0.22. For CIS-based absorber layers fabricated using conventional SAS methods, the ratio of [S] to [S]+[Se] was shown to be 0.25. Thus, the conventional SAS method results in CIS-based absorber layers with a higher concentration of sulfur than for fabrication methods using embodiments of the present subject matter.

Depicted in FIG. 9A is a cross-section of certain layers of a thin film solar cell fabricated according to embodiments of the present subject matter showing specifically the CIS-based absorber layer 902A and the window layer 901A. Depicted in FIG. 9B is a cross-section of certain layers of a conventional thin film solar cell fabricated using conventional SAS methods showing specifically the CIS-based absorber layer 902B and the window layer 901B. The precursor film used during the fabrication of the thin film solar cell in FIG. 9A was identical to the precursor film used during the fabrication of the thin film solar cell in FIG. 9B. These cross-sections were taken using a scanning electron microscope (“SEM”). As can be seen from a comparison of FIGS. 9A and 9B, the absorber layer 902A is thicker than the absorber layer 902B.

FIG. 10 is a cross-section of a CIS-based absorber layer fabricated according to embodiments of the present subject matter. The cross section was taken using SEM. As can be seen from FIG. 10, the grain size of the absorber layer is ≧1 μm. Typical grain sizes for absorber layers fabricated using conventional SAS methods is ≧1 μm. Due to the larger grain size, there are fewer grain boundaries and therefore fewer recombination losses through the grain boundaries. Additionally, a thicker absorber layer can be produced (using the same source material as for conventional SAS) which will be more effective in absorbing light.

The following table offers a brief summary of various attributes of the multi-source co-evaporation method, the conventional SAS method, and methods according to embodiments of the present subject matter:

| | | | EMBODIMENTS |
|---|---|---|---|
| | MULTI- | | OF THE |
| | SOURCE | CONVEN- | PRESENT |
| | CO- | TIONAL | SUBJECT |
| ATTRIBUTE | EVAPORATION | SAS | MATTER |
| Uniformity of | LOW | HIGH | HIGH |
| absorber layer | | | |
| composition | | | |
| over a large area | | | |
| Utility of source | LOW | MEDIUM | HIGH |
| materials | | | |
| Absorber layer | COMPLICATED | SIMPLY | SIMPLE |
| forming | AND EXPENSIVE | AND LESS | AND LESS |
| equipment | | COSTLY | COSTLY |
| Controllability | HIGH | LOW | MEDIUM |
| of composition | | | |
| profile in | | | |
| absorber layer | | | |
| Grain size of | LARGE | SMALL | MEDIUM |
| absorber layer | | | |

Some embodiments include a method for manufacturing an absorber layer for a device where the method includes the steps of providing an object having a precursor film and a metal back electrode layer on a substrate, performing a first process on the object at a first temperature (“T₁”) for a first time period (“Δt₁”), performing a second process on the object at a second temperature (“T₂”) for a second time period (“Δt₂”), and performing a third process on the object at a third temperature (“T₃”) for a third time period (“Δt₃”). The device may be a thin film solar cell. In some embodiments, the precursor film is a metal precursor and may comprise copper, gallium, indium, and alloys thereof. In other embodiments, the precursor film is a CIS-based semiconductor and may comprise a pentanary Cu-III-VI₂ group chalcopyrite semiconductor. In some embodiments, the CIS-based semiconductor comprises one or more of the following materials: CuInSe₂, CuGaSe₂, Cu(InGa)Se₂, CuInS₂, CuGaS₂, Cu(InGa)S₂, CuIn(Se,S)₂, CuGa(Se,S)₂, Cu(InGa)(Se,S)₂, and combinations thereof.

In other embodiments, the first process includes holding the object in an atmosphere containing a selenium source, where 200° C.≦T₁≦800° C. and where 0 min.≦Δt₁≦300 min. In certain embodiments, the selenium source is hydrogen selenide.

In further embodiments, the second process includes holding the object in an inert gas atmosphere, where 200° C.≦T₂≦800° C., 0 min.≦Δt₂≦300 min., and where T₁≦T₂. In certain embodiments, the inert gas is nitrogen or argon.

In still further embodiments, the third process includes holding the object in an atmosphere containing a sulfur source, where 200° C.≦T₃≦600° C., 0 min.≦Δt₃≦300 min., and where T₃≦T₂. In certain embodiments, the sulfur source is hydrogen sulfide.

In another embodiment, the first process includes holding the object in an atmosphere containing a selenium source, where 350° C.≦T₁≦650° C. and where 0 min.≦Δt₁≦300 min. In certain embodiments, the selenium source is hydrogen selenide.

In yet another embodiment, the second process includes holding the object in an inert gas atmosphere, where 450° C.≦T₂≦700° C., 0 min.≦Δt₂≦300 min., and where T₁≦T₂. In certain embodiments, the inert gas is nitrogen or argon.

In still another embodiment, the third process includes holding the object in an atmosphere containing a sulfur source, where 450° C.≦T₃≦550° C., 0 min.≦Δt₃≦300 min., and where T₃≦T₂. In certain embodiments, the sulfur source is hydrogen sulfide.

Still other embodiments include a method for manufacturing an absorber layer for a treatment object where the method includes the steps of providing the treatment object having a precursor, holding the object at a first temperature (“T₁”) for a first time period (“Δt₁”) in an inert gas atmosphere, where 200° C.≦T₂≦800° C., 0 min.≦Δt₂≦300 min., and holding the object at a second temperature (“T₂”) for a second time period (“Δt₂”) in an atmosphere containing a sulfur source, where 200° C.≦T₃≦600° C., 0 min.≦Δt₃≦300 min., and where T₂≦T₁.

In other embodiments, the precursor is a CIS-based semiconductor or a metal precursor including selenium and/or sulfur.

In other embodiments, the device is a thin film solar cell, and the precursor film is either a metal precursor or a CIS-based semiconductor having a pentanary Cu-III-VI₂ group chalcopyrite semiconductor. In still other embodiments, the device is a thin film solar cell.

Yet other embodiments include a thin film solar cell having a substrate layer, a back electrode layer, and a CIS-based absorber layer having a surface-to-bottom ratio of the concentration of gallium that is at least 0.4. In further embodiments, the surface-to-bottom ratio of the concentration of gallium is between 0.4 and 0.55. In still further embodiments, the CIS-based absorber layer further has a ratio of a concentration of sulfur to a concentration of sulfur-plus-selenium of less than 0.2. In yet further embodiments, the CIS-based absorber layer has a ratio of a concentration of sulfur to a concentration of sulfur-plus-selenium that is between 0.15 and 0.22.

While some embodiments of the present subject matter have been described, it is to be understood that the embodiments described are illustrative only and that the scope of the invention is to be defined solely by the appended claims when accorded a full range of equivalence, many variations and modifications naturally occurring to those of skill in the art from a perusal hereof.

We claim:

1. A method for manufacturing an absorber layer for a device, the method comprising the steps of:
(a) providing an object comprising a precursor film and a metal back electrode layer on a substrate;
(b) performing a first process on said object at a first temperature (“T₁”) for a first time period (“Δt₁”);
(c) performing a second process on said object at a second temperature (“T₂”) for a second time period (“Δt₂”); and
(d) performing a third process on said object at a third temperature (“T₃”) for a third time period (“Δt₃”).

2. The method of claim 1 wherein the device is a thin film solar cell.

3. The method of claim 1 wherein said precursor film is a metal precursor.

4. The method of claim 3 wherein said metal precursor comprises a material selected from the group consisting of: copper, gallium, indium, selenium, sulfur, and alloys thereof.

5. The method of claim 1 wherein said precursor film is a CIS-based semiconductor.

6. The method of claim 5 wherein said CIS-based semiconductor comprises a pentanary Cu-III-VI₂ group chalcopyrite semiconductor.

7. The method of claim 5 wherein said CIS-based semiconductor comprises a material selected from the group consisting of: CuInSe₂, CuGaSe₂, Cu(InGa)Se₂, CuInS₂, CuGaS₂, Cu(InGa)S₂, CuIn(Se,S)₂, CuGa(Se,S)₂, Cu(InGa)(Se,S)₂, and combinations thereof.

8. The method of claim 1 wherein the first process comprises holding said object in an atmosphere containing a selenium source, and wherein 200° C.≦T₁≦800° C. and 0 min.≦Δt₁≦300 min.

9. The method of claim 8 wherein the selenium source is hydrogen selenide.

10. The method of claim 1 wherein the second process comprises holding said object in an inert gas atmosphere, and wherein 200° C.≦T₂≦800° C. and 0 min.≦Δt₂≦300 min., and wherein T₁≦T₂.

11. The method of claim 10 wherein the inert gas is nitrogen or argon.

12. The method of claim 1 wherein the third process comprises holding said object in an atmosphere containing a sulfur source, and wherein 200° C.≦T₃≦600° C. and 0 min.≦Δt₃≦300 min., and wherein T₃≦T₂.

13. The method of claim 12 wherein the sulfur source is hydrogen sulfide.

14. A method for manufacturing an absorber layer for a device, the method comprising the steps of:
(a) providing an object comprising a precursor;
(b) holding said object at a first temperature (“T₁”) for a first time period (“Δt₁”) in an inert gas atmosphere, wherein 200° C.≦T₁≦800° C. and 0 min.≦Δt₁≦300 min.; and
(c) holding said object at a second temperature (“T₂”) for a second time period (“Δt₂”) in an atmosphere containing a sulfur source, wherein 200° C.≦T₂≦600° C. and 0 min.≦Δt₂≦300 min., and wherein T₂≦T₁.

15. The method of claim 14 wherein the device is a thin film solar cell, and wherein said precursor is a CIS-based semiconductor or a metal precursor comprising selenium and/or sulfur.

16. The method of claim 14 wherein the device is a thin film solar cell.

17. A thin film solar cell, comprising:
a substrate layer;
a back electrode layer; and
a CIS-based absorber layer having a surface-to-bottom ratio of the concentration of gallium that is at least 0.4.

18. The thin film solar cell of claim 17 wherein the surface-to-bottom ratio of the concentration of gallium is between 0.4 and 0.55.

19. The thin film solar cell of claim 17 wherein the CIS-based absorber layer further has a ratio of a concentration of sulfur to a concentration of sulfur-plus-selenium of less than 0.2.

20. The thin film solar cell of claim 17 wherein the CIS-based absorber layer further has a ratio of a concentration of sulfur to a concentration of sulfur-plus-selenium that is between 0.15 and 0.22.
